(19) United States
(12) Patent Application Publication
(10) Pub. No.: US 2013/0328449 A1
(43) Pub. Date: Dec. 12, 2013

(54) PIEZOELECTRIC VIBRATING PIECE AND PIEZOELECTRIC DEVICE

(71) Applicant: NIHON DEMPA KOGYO CO., LTD., Tokyo (JP)

(72) Inventors: TAKEHIRO TAKAHASHI, SAITAMA (JP); SHUICHI MIZUSAWA, SAITAMA (JP)

(21) Appl. No.: 13/911,079

(22) Filed: Jun. 6, 2013

(30) Foreign Application Priority Data
Jun. 12, 2012 (JP) 2012-132642

(51) Int. Cl. H01L 41/047; H01L 41/053

(52) U.S. Cl. CPC H01L 41/0475; H01L 41/053
USPC 310/344; 310/348

(57) ABSTRACT

A piezoelectric vibrating piece includes a vibrator, a framing portion, and a connecting portion. The vibrator vibrates at a predetermined vibration frequency. The vibrator includes excitation electrodes on both principal surfaces. The vibrator is formed at a predetermined thickness. The framing portion surrounds a peripheral area of the vibrator. The connecting portion connects the vibrator and the framing portion. The vibrator has a side surface. At least a part of the side surface is formed into a taper shape such that a thickness of the vibrator becomes thin as close to an outer periphery of the vibrator. The piezoelectric vibrating piece further includes an extraction electrode extracted from each of the excitation electrodes to the framing portion via the connecting portions. One of the extraction electrodes is extracted from one principal surface to another principal surface via a taper-shaped side surface of the vibrator.

### CROSS REFERENCE TO RELATED APPLICATIONS

This application claims the priority benefit of Japan application serial no. 2012-132642, filed on Jun. 12, 2012. The entirety of the above-mentioned patent application is hereby incorporated by reference herein and made a part of this specification.

### TECHNICAL FIELD

This disclosure relates to a piezoelectric vibrating piece where a framing portion is formed and a piezoelectric device.

### DESCRIPTION OF THE RELATED ART

A piezoelectric vibrating piece that includes a vibrator vibrating at a predetermined vibration frequency, a framing portion surrounding the vibrator, and a connecting portion connecting the vibrator and the framing portion is known. This piezoelectric vibrating piece forms a piezoelectric device where a base plate and a lid plate are bonded respectively on one principal surface and the other principal surface of a framing portion via a bonding material. The piezoelectric vibrating piece includes a pair of excitation electrodes on both principal surfaces of a vibrator. Extraction electrodes are extracted from the excitation electrodes to the framing portion, respectively.

A pair of extraction electrodes formed on the piezoelectric vibrating piece electrically connect to mounting terminals formed on a base plate to be bonded on one principal surface of the piezoelectric vibrating piece. Accordingly, the extraction electrode of the piezoelectric vibrating piece extracted from the excitation electrode formed on a principal surface facing a lid plate is extracted to a principal surface of the framing portion facing the base plate. At this time, the extraction electrode is formed via at least one side surface of the vibrator, the connecting portion, or the framing portion. For example, Japanese Unexamined Patent Application Publication No. 2012-90081 (hereinafter referred to as Patent Literature 1) discloses a piezoelectric vibrating piece where an extraction electrode is formed at a side surface of the connecting portion.

However, Patent Literature 1 has a problem as follows. The extraction electrode is extracted from a principal surface to a side surface mainly via a corner formed at a right angle between the principal surface and the side surface of the connecting portion or similar member. This causes disconnection of the extraction electrode or an increase in an electrical resistance, resulting in an increase in crystal impedance (CI) of the piezoelectric vibrating piece.

A need thus exists for a piezoelectric vibrating piece and a piezoelectric device which are not susceptible to the drawback mentioned above.

### SUMMARY

A piezoelectric vibrating piece includes a vibrator, a framing portion, and a connecting portion. The vibrator vibrates at a predetermined vibration frequency. The vibrator includes excitation electrodes on both principal surfaces. The vibrator is formed at a predetermined thickness. The framing portion surrounds a peripheral area of the vibrator. The connecting portion connects the vibrator and the framing portion. The vibrator has a side surface. At least a part of the side surface is formed into a taper shape such that a thickness of the vibrator becomes thin as close to an outer periphery of the vibrator. The piezoelectric vibrating piece further includes an extraction electrode extracted from each of the excitation electrodes to the framing portion via the connecting portions. One of the extraction electrodes is extracted from one principal surface to another principal surface via a taper-shaped side surface of the vibrator.

### BRIEF DESCRIPTION OF THE DRAWINGS

The foregoing and additional features and characteristics of this disclosure will become more apparent from the following detailed description considered with reference to the accompanying drawings, wherein:

FIG. 1 is an exploded perspective view of a piezoelectric device 100;

FIG. 2 is a cross-sectional view taken along the line A-A of FIG. 1;

FIG. 3(a) is a plan view of a piezoelectric vibrating piece 130;

FIG. 3(b) is a plan view of the piezoelectric vibrating piece 130 on a surface at the −Y′-axis side viewed from the +Y′-axis side;

FIG. 3(c) are cross-sectional views taken along the line B-B of FIG. 3(a) and FIG. 3(b);

FIG. 4 is a plan view of a piezoelectric wafer W130;

FIG. 5(a) to FIG. 5(d) are flowcharts illustrating a process where the piezoelectric vibrating piece 130 is formed on the piezoelectric wafer W130;

FIG. 6(a) to FIG. 6(d) are flowcharts illustrating a process where the piezoelectric vibrating piece 130 is formed on the piezoelectric wafer W130;

FIG. 7(a) is a plan view of a piezoelectric vibrating piece 230;

FIG. 7(b) is a cross-sectional view taken along the line D-D of FIG. 7(a);

FIG. 8(a) is a plan view of a piezoelectric vibrating piece 330; and

FIG. 8(b) is a plan view of the piezoelectric vibrating piece 330 on a surface at the −Y′-axis side viewed from the +Y′-axis side.

### DETAILED DESCRIPTION

The preferred embodiments of this disclosure will be described with reference to the attached drawings. It will be understood that the scope of the disclosure is not limited to the described embodiments, unless otherwise stated.

### Constitution of a Piezoelectric Device 100 According to a First Embodiment

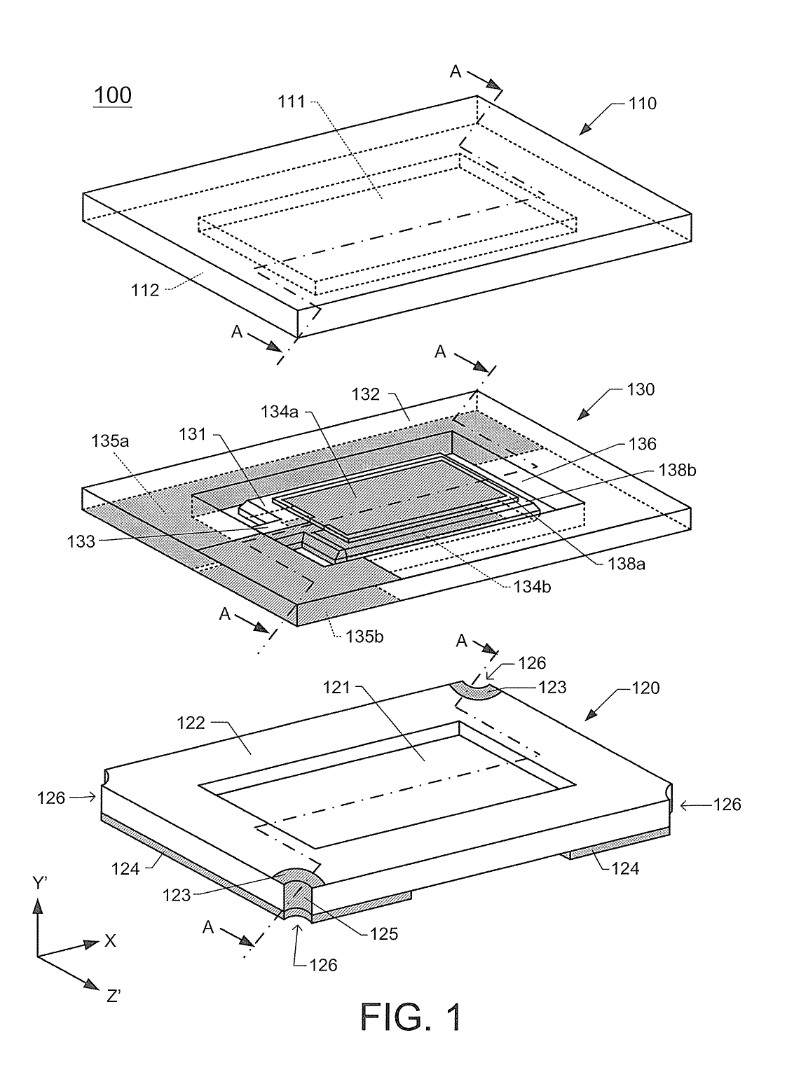

FIG. 1 is an exploded perspective view of the piezoelectric device 100. The piezoelectric device 100 includes a lid plate 110, a base plate 120, and a piezoelectric vibrating piece 130. An AT-cut quartz-crystal vibrating piece, for example, is employed for the piezoelectric vibrating piece 130. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular to the X and Y′-axis directions as the Z′-axis direction.

The piezoelectric vibrating piece 130 includes a vibrator 131, a framing portion 132, and a connecting portion 133. The vibrator 131 vibrates at a predetermined vibration frequency and has a rectangular shape. The framing portion 132 surrounds the vibrator 131. The connecting portion 133 connects the vibrator 131 and the framing portion 132. A through groove 136 that passes through the piezoelectric vibrating piece 130 in the Y′-axis direction is formed between the vibrator 131 and the framing portion 132. The connecting portion 133 connects the center of the side at the −X-axis side of the vibrator 131 and the side surface at the −X-axis side of the framing portion 132. The vibrator 131 includes an excitation electrode 134a on the surface at the +Y′-axis side and an excitation electrode 134b on the surface at the −Y′-axis side. An extraction electrode 135a is extracted from the excitation electrode 134a to the −X-axis side and the +Z′-axis side of the framing portion 132 via the connecting portion 133 on the surface at the −Y′-axis side. An extraction electrode 135b is extracted from the excitation electrode 134b to the +X-axis side and the −Z′-axis side of the framing portion 132 via the connecting portion 133 on the surface at the −Y′-axis side. Additionally, the vibrator 131 includes a mesa region 138a and a peripheral region 138b. The mesa region 138a includes the excitation electrode 134a and the excitation electrode 134b. The peripheral region 138b surrounds the mesa region 138a and is thinner than the mesa region 138a in the Y′-axis direction.

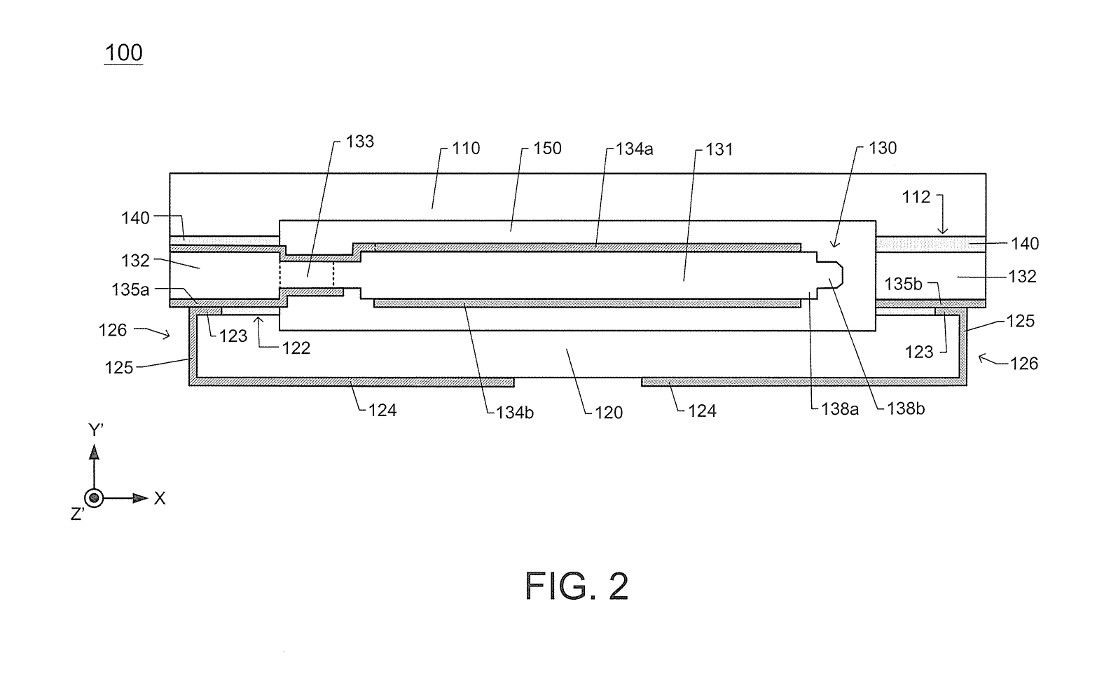

The base plate 120 includes a depressed portion 121 depressed at the −Y′-axis side, a bonding surface 122, and connecting electrodes 123 on the surface at the +Y′-axis side. The bonding surface 122 surrounds the depressed portion 121. The connecting electrodes 123 are disposed at the corner of the +X-axis side and the −Z′-axis side and at the corner of the −X-axis side and the +Z′-axis side of the bonding surface 122. The bonding surface 122 is to be bonded on the surface at the −Y′-axis side of the framing portion 132 of the piezoelectric vibrating piece 130 via a bonding material 140 (see FIG. 2). Additionally, a pair of mounting terminals 124 is formed on the surface at the −Y′-axis side of the base plate 120. Furthermore, castellations 126 are formed at four corners of side surfaces of the base plate 120. Castellation electrodes 125 are formed at the side surface at the +X-axis side and the −Z′-axis side and the side surface at the −X-axis side and the +Z′-axis side of the castellations 126. The castellation electrode 125 electrically connects the connecting electrode 123 and the mounting terminal 124. The connecting electrode 123 formed at the corner at the −X-axis side and at the +Z′-axis side electrically connects to the extraction electrode 135a extracted to the corner at the −X-axis side and at the +Z′-axis side on the surface at the −Y′-axis side of the piezoelectric vibrating piece 130. The connecting electrode 123 formed at the corner at the +X-axis side and at the −Z′-axis side electrically connects to the extraction electrode 135b extracted to the corner at the +X-axis side and at the −Z′-axis side on the surface at the −Y′-axis side of the piezoelectric vibrating piece 130.

The lid plate 110 includes a depressed portion 111 and a bonding surface 112 on the surface at the −Y′-axis side. The bonding surface 112 surrounds the depressed portion 111. The bonding surface 112 is to be bonded to the framing portion 132 on the surface at the +Y′-axis side of the piezoelectric vibrating piece 130 via the bonding material 140 (see FIG. 2).

FIG. 2 is a cross-sectional view taken along the line A-A of FIG. 1. The piezoelectric device 100 includes the lid plate 110 at the +Y′-axis side and the base plate 120 at the −Y′-axis side of the piezoelectric vibrating piece 130. Additionally, the piezoelectric device 100 includes a cavity 150 formed by the depressed portion 111 of the lid plate 110 and the depressed portion 121 of the base plate 120. The vibrator 131 of the piezoelectric vibrating piece 130 is disposed in the cavity 150. The cavity 150 is sealed by forming the bonding materials 140 between the bonding surface 112 of the lid plate 110 and the surface at the +Y′-axis side of the framing portion 132, and between the bonding surface 122 of the base plate 120 and the surface at the −Y′-axis side of the framing portion 132. When the extraction electrode 135a and the extraction electrode 135b formed at the framing portion 132 electrically connect to the connecting electrodes 123 formed at the base plate 120, the excitation electrode 134a and the excitation electrode 134b electrically connect to the mounting terminals 124.

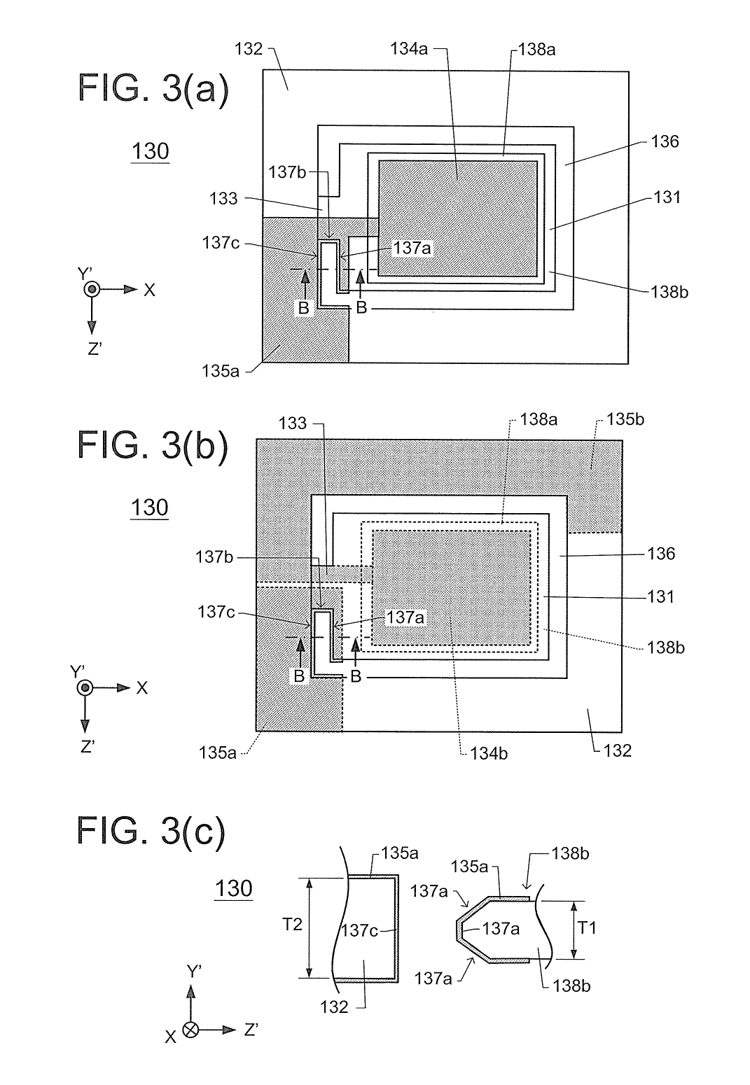

FIG. 3(a) is a plan view of the piezoelectric vibrating piece 130. The piezoelectric vibrating piece 130 includes the excitation electrode 134a and the extraction electrode 135a on the surface at the +Y′-axis side. The excitation electrode 134a is formed in the mesa region 138a of the vibrator 131. The extraction electrode 135a extends from the excitation electrode 134a in the −X-axis direction to the −X-axis side and the +Z′-axis side of the framing portion 132 via the connecting portion 133. Further, the extraction electrode 135a is extracted to the surface at the −Y′-axis side mainly via a side surface 137a at the −X-axis side and the +Z′-axis side of the vibrator 131, a side surface 137b at the +Z′-axis side of the connecting portion 133, and a side surface 137c at the −X-axis side and the +Z′-axis side of an inner side surface at the framing portion 132 facing the vibrator 131.

FIG. 3(b) is a plan view of the piezoelectric vibrating piece 130 on the surface at the −Y′-axis side viewed from the +Y′-axis side. The extraction electrode 135b extends in the −X-axis direction from the excitation electrode 134b formed in the mesa region 138a on the vibrator 131 on the surface at the −Y′-axis side and further extends to the +X-axis side and the −Z′-axis side of the framing portion 132 on the surface at the −Y′-axis side via the connecting portion 133. The extraction electrode 135a extracted from the surface at the +Y′-axis side via the side surfaces 137a, 137b, and 137c are further extracted to the corner at the −X-axis side and the +Z′-axis side of the framing portion 132 on the surface at the −Y′-axis side.

FIG. 3(c) is a cross-sectional view taken along the line B-B of FIG. 3(a) and FIG. 3(b). The extraction electrode 135a formed at the vibrator 131 on the surface at the +Y′-axis side is extracted to the vibrator 131 on the surface at the −Y′-axis side via the side surface 137a. Further, the extraction electrode 135a formed at the framing portion 132 at the +Y′-axis side is extracted to the framing portion 132 on the surface at the −Y′-axis side via the side surface 137c. With the piezoelectric vibrating piece 130, assume that the thickness of the peripheral region 138b in the vibrator 131 in the Y′-axis direction is thickness T1 and the thickness of the framing portion 132 in the Y′-axis direction is thickness T2. Then, the thickness T1 is formed thinner than the thickness T2. Additionally, the side surfaces 137a at the +Y′-axis side and the −Y′-axis side of the vibrator 131 are formed into a taper shape such that the vibrator 131 becomes thin as close to an outer periphery of the vibrator 131.

### Method for Fabricating the Piezoelectric Vibrating Piece 130

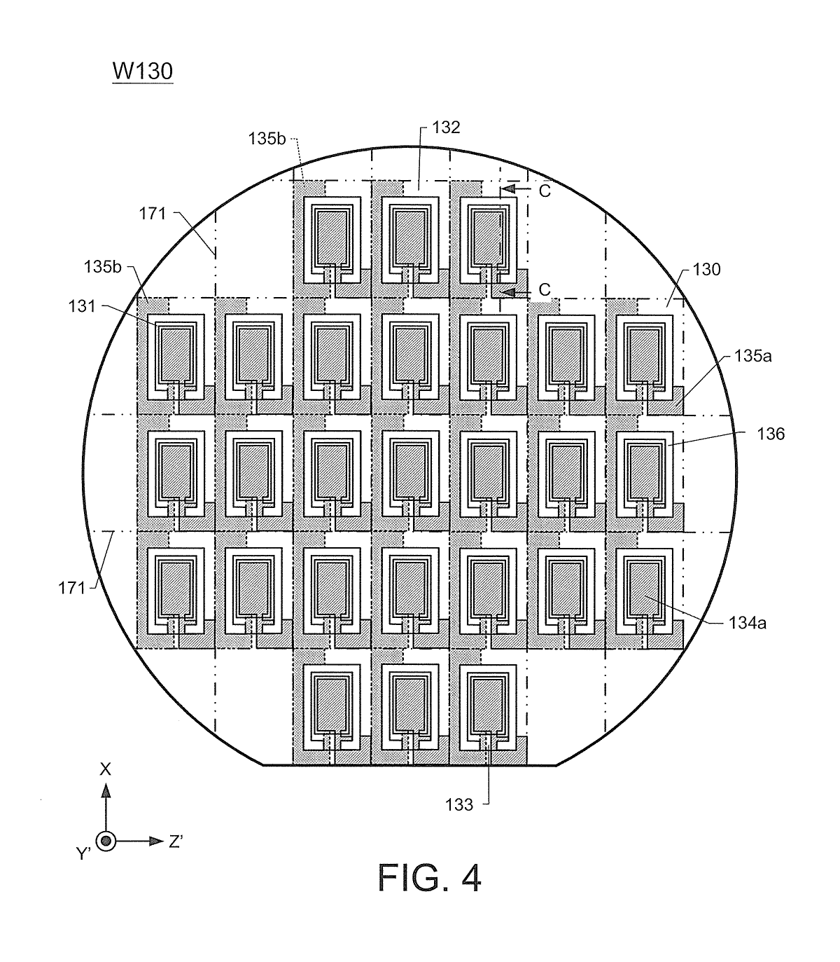

FIG. 4 is a plan view of a piezoelectric wafer W130. The outline of the plurality of piezoelectric vibrating pieces 130 is formed on the piezoelectric wafer W130 made of a piezoelectric material. Then, the excitation electrode 134a, the excitation electrode 134b, the extraction electrode 135a, and the extraction electrode 135b are formed to fabricate the piezoelectric vibrating piece 130. The piezoelectric wafer W130 illustrated in FIG. 4 includes the plurality of piezoelectric vibrating pieces 130 aligned in the X-axis direction and the Z′-axis direction. A scribe line 171 is drawn between the piezoelectric vibrating pieces 130 neighboring one another. After the piezoelectric wafer W130 is formed, dicing the piezoelectric wafer W130 along the scribe line 171 divides the piezoelectric vibrating pieces 130 individually.

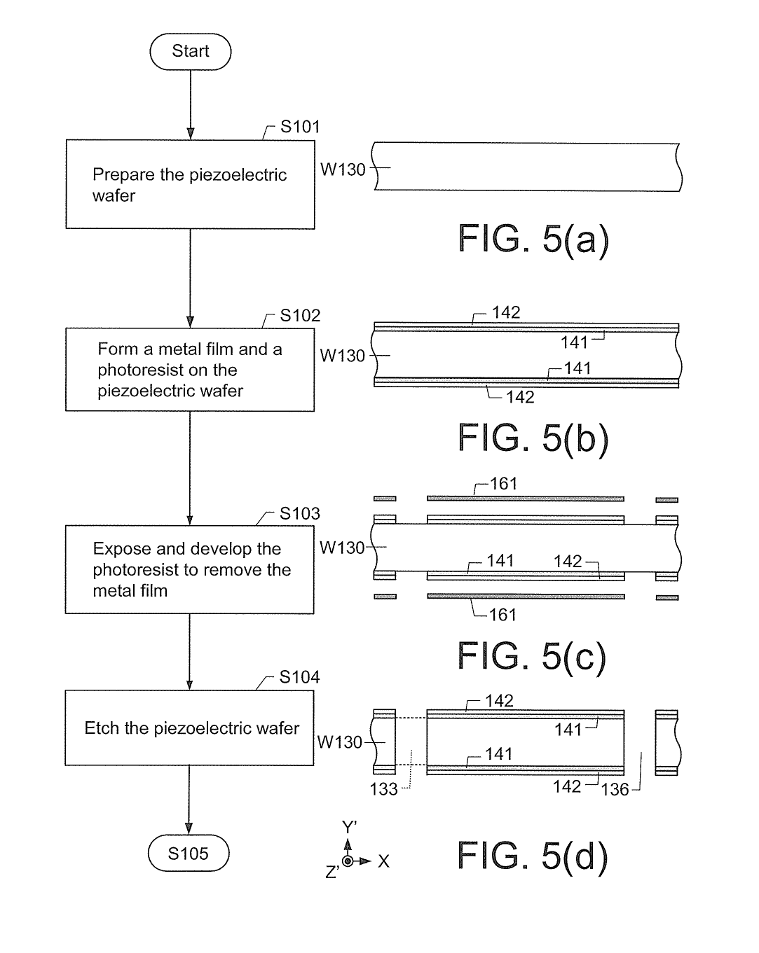

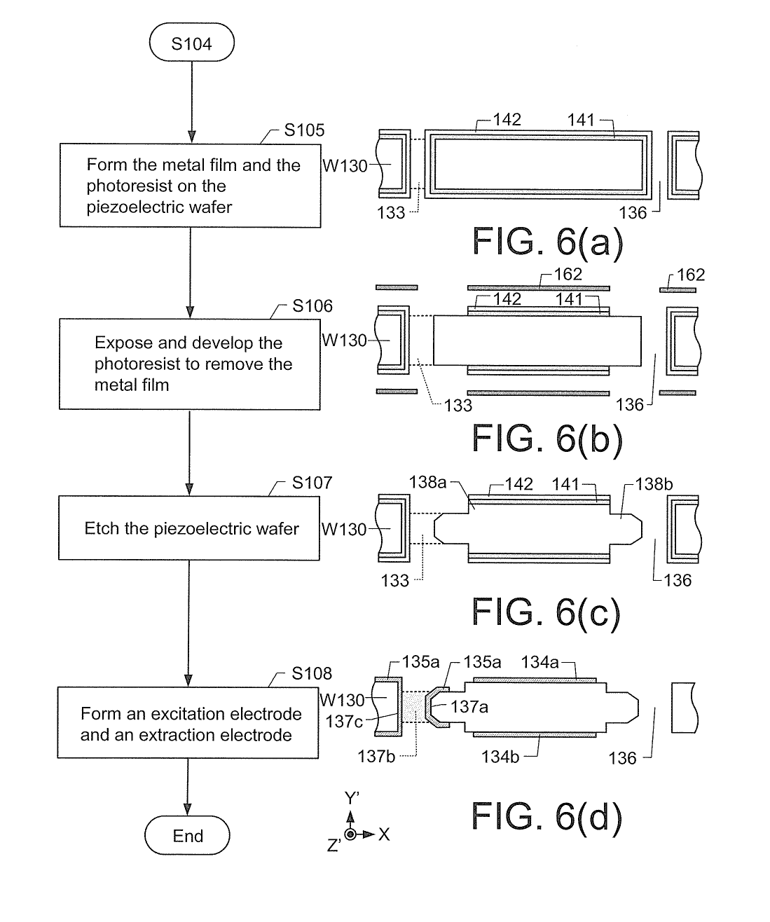

FIG. 5(a) to FIG. 5(d) and FIG. 6(a) to FIG. 6(d) are flowcharts illustrating a process where the piezoelectric vibrating piece 130 is formed on the piezoelectric wafer W130. FIG. 5(a) to FIG. 5(d) and FIG. 6(a) to FIG. 6(d) illustrate a partial cross-sectional view of the piezoelectric wafer W130, which describes each step of the flowchart, to the right of each step. These partial cross-sectional views correspond to a cross section taken along the line C-C of FIG. 4. A description will be given of a process where the piezoelectric vibrating piece 130 is formed on the piezoelectric wafer W130 according to the flowcharts illustrated in FIG. 5(a) to FIG. 5(d) and FIG. 6(a) to FIG. 6(d).

In step S101 of FIG. 5(a), the piezoelectric wafer W130 is prepared. FIG. 5(a) is a partial cross-sectional view of the piezoelectric wafer W130 prepared in step S101. The piezoelectric wafer W130 prepared in step S101 has flat surfaces at the +Y′-axis side and the −Y′-axis side.

In step S102, a metal film 141 and a photoresist 142 are formed on both surfaces at the +Y′-axis side and the −Y′-axis side of the piezoelectric wafer W130. FIG. 5(b) is a partial cross-sectional view of the piezoelectric wafer W130 where the metal film 141 and the photoresist 142 are formed. In step S102, first, the metal film 141 is formed on the piezoelectric wafer W130 prepared in step S101. Further, the photoresist 142 is formed on the surface of the metal film 141. Performing sputtering, vacuum evaporation, or similar method on a predetermined metal at the piezoelectric wafer W130 forms the metal film 141. For example, the metal film 141 is formed as follows. A film made of a material such as nickel (Ni), chrome (Cr), titanium (Ti), or nickel tungsten (NiW) is formed on the piezoelectric wafer W130 as a foundation layer. Then, a film made of a material such as gold (Au) or silver (Ag) is formed on the top surface of the foundation layer. The photoresist 142 is uniformly applied over the surface of the metal film 141 by a method such as spin coat.

In step S103, the photoresist 142 is exposed and developed to remove the metal film 141. FIG. 5(c) is a partial cross-sectional view of the piezoelectric wafer W130 where the photoresist 142 is exposed and developed to remove the metal film 141. In step S103, first, masks 161 are disposed at the +Y′-axis side and the −Y′-axis side of the piezoelectric wafer W130, and the photoresist 142 is exposed then developed. Furthermore, the metal film 141 is removed by etching. The photoresists 142, which are exposed using the masks 161, are on the surfaces at the +Y′-axis side and the −Y′-axis side where the through groove 136 is formed. The photoresists 142 and the metal films 141 at this region are removed.

In step S104, the piezoelectric wafer W130 is etched to form the through groove 136. FIG. 5(d) is a partial cross-sectional view of the piezoelectric wafer W130 where the through groove 136 is formed. In step S104, etching the piezoelectric wafer W130 forms the through groove 136 passing through the piezoelectric wafer W130 in the Y′-axis direction.

In step S105 of FIG. 6(a), the metal film 141 and the photoresist 142 are formed on the piezoelectric wafer W130. FIG. 6(a) is a partial cross-sectional view of the piezoelectric wafer W130 where the metal film 141 and the photoresist 142 are formed. In step S105, all the metal film 141 and the photoresist 142 remain in step S104 are removed, and the metal film 141 and the photoresist 142 are formed again on the entire piezoelectric wafer W130.

In step S106, the photoresist 142 is exposed and developed to remove the metal film 141. FIG. 6(b) is a partial cross-sectional view of the piezoelectric wafer W130 where the photoresist 142 is exposed and developed to remove the metal film 141. In step S106, the photoresist 142 formed at the peripheral region 138b of the vibrator 131 and the connecting portion 133 are exposed via the mask 162, and the photoresist 142 is developed. Furthermore, the metal film 141 is removed by etching. In step S106, the peripheral region 138b of the vibrator 131 and the connecting portion 133 are exposed.

In step S107, the piezoelectric wafer W130 is etched. FIG. 6(c) is a partial cross-sectional view of the etched piezoelectric wafer W130. In step S107, the peripheral region 138b of the piezoelectric wafer W130 is formed thin by etching. Thus, the mesa region 138a is formed. Additionally, corners between the principal surface and side surfaces of the outer periphery of the peripheral region 138b are etched from two directions: the Y′-axis direction, and the side surface facing the through groove 136. Accordingly, the side surfaces at the +Y′-axis side and the −Y′-axis side of the peripheral region 138b are formed into a taper shape as illustrated in FIG. 3(c) and FIG. 6(c).

In step S108, an excitation electrode and an extraction electrode are formed on the piezoelectric wafer W130. FIG. 6(d) is a partial cross-sectional view of the piezoelectric wafer W130 where the excitation electrode and the extraction electrode are formed. In step S108, after all photoresist 142 and metal film 141 are removed from the piezoelectric wafer W130 of FIG. 6(c), the excitation electrode 134a, the excitation electrode 134b, the extraction electrode 135a, and the extraction electrode 135b are formed on the piezoelectric wafer W130. The extraction electrode 135a is formed across the surface at the +Y′-axis side and the surface at the −Y′-axis side via the side surface 137a. Additionally, the extraction electrodes 135a are also formed at the side surface 137b of the connecting portion 133 and the side surface 137c of the framing portion 132. After step S108, each piezoelectric vibrating piece 130 is individually diced at the scribe line 171.

In the piezoelectric vibrating piece, in the case where the extraction electrode is extracted from the principal surface at the +Y′-axis side to the principal surface at the −Y′-axis side, increases in electrical resistance or poor conduction can occur at the extraction electrode at a corner between the principal surface and the side surface or similar portion. Therefore, a crystal impedance (CI) of the piezoelectric vibrating piece may increase. In the case where electrical resistance increases or poor conduction of the extraction electrode occurs, forming an extraction electrode at this corner is difficult if the angle of the corner between the principal surface and the side surface is almost a right angle. This is due to the following reasons. Under such conditions, applying the photoresist, an exposure condition of the photoresist, or similar must be strictly controlled. Additionally, in formation of the electrode at the side surface by sputtering or similar method, the material of the electrode is difficult to wrap around the side surface. This also thins the film thickness of the side surface. Meanwhile, in the piezoelectric vibrating piece 130, the side surface of the vibrator 131 is formed into a taper shape such that the angle of the corner between the principal surface and the side surface of the vibrator 131 may be greater than 90 degrees. This facilitates better control over application and exposure conditions of the photoresist or similar, also facilitating forming the extraction electrode at the corner. Additionally, the material of the electrode easily wraps around the taper-shaped side surface. This reduces the film thickness of the side surface to be thin. Accordingly, increased electrical resistance, poor conduction of the extraction electrode 135a, or similar condition are less likely to occur. This allows reduced crystal impedance (CI) and maintaining low crystal impedance (CI) at the same time.

Additionally, with the piezoelectric vibrating piece 130, the extraction electrode 135a is extracted from the surface at the +Y′-axis side to the surface at the −Y′-axis side via the side surface of the through groove 136. When the extraction electrode 135a is formed at the side surface of the through groove 136, a metal film, which constitutes an electrode, also attaches around a region where the extraction electrode 135a is extracted. That is, if an attempt to form an extraction electrode only at the inner side surface of the framing portion 132 facing the vibrator 131 is made, a metal film is also formed at the vibrator 131 around the extraction electrode via the through groove 136. Thus, the metal film formed at the vibrator 131 negatively affects the vibration of the vibrator 131. With the piezoelectric vibrating piece 130, forming the extraction electrode 135a around the connecting portion 133 and at the connecting portion 133, which originally negatively affects the vibration, is less likely to induce a negative effect caused by forming the extraction electrode 135a at a part of the vibrator 131, which is preferred.

Additionally, with the piezoelectric vibrating piece 130, forming the extraction electrode 135a at the side surface 137b of the connecting portion 133 and the side surface 137c of the framing portion 132 expands the width of the extraction electrode 135a extracted from the surface at the +Y′-axis side to the surface at the −Y′-axis side. This further reduces the electrical resistance of the extraction electrode 135a, which is preferred. Additionally, with the piezoelectric vibrating piece 130, the side surface 137b of the connecting portion 133 is also formed into a taper shape. This reduces an occurrence of poor conduction, an increase in electrical resistance of the extraction electrode 135a, or similar situation, which is preferred.

### Second Embodiment

The piezoelectric vibrating piece may have an outer shape different from the piezoelectric vibrating piece 130. A description will be given of a piezoelectric vibrating piece 230 and a piezoelectric vibrating piece 330 as a modification of a piezoelectric vibrating piece. Like reference numerals designate corresponding or identical elements throughout the first embodiment and the second embodiment, and therefore such elements will not be further elaborated here.

### Constitution of the Piezoelectric Vibrating Piece 230

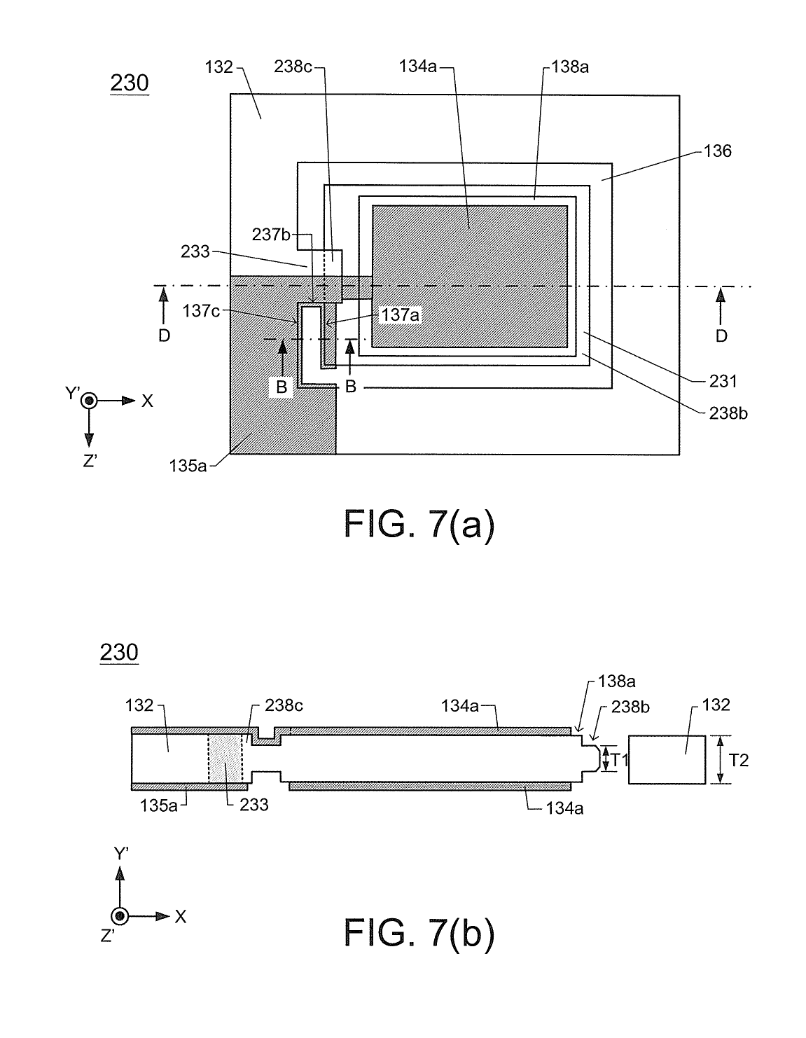

FIG. 7(a) is a plan view of the piezoelectric vibrating piece 230. The piezoelectric vibrating piece 230 includes a vibrator 231, the framing portion 132, and a connecting portion 233. The vibrator 231 is formed into a rectangular shape where the long side extends in the X-axis direction and the short side extends in the Z′-axis direction in a planar shape. The connecting portion 233 connects the center of the side at the −X-axis side of the vibrator 231 and the inner side surface at the −X-axis side of the framing portion 132. Further, the mesa region 138a is formed at the vibrator 231, a connecting region 238c is formed at a part connected to the connecting portion 233, and a peripheral region 238b is formed at a region other than the mesa region 138a and the connecting region 238c. The connecting region 238c is formed at the center of the side at the −X-axis side of the vibrator 231 and not connected to the mesa region 138a. The piezoelectric vibrating piece 230 also includes the excitation electrode 134a, the excitation electrode 134b, the extraction electrode 135a, and the extraction electrode 135b. The extraction electrode 135a is mainly extracted to the surface at the −Y′-axis side via the side surface 137a at the −X-axis side and the +Z′-axis side of the vibrator 231, a side surface 237b at the −Z′-axis side of the connecting portion 233, and the side surface 137c at the inner side surface at the −X-axis side and the +Z′-axis side of the framing portion 132 facing the vibrator 131. The piezoelectric vibrating piece 230 has a planar surface at the −Y′-axis side similar to that of FIG. 3(b). The cross section taken along the line B-B of FIG. 7(a) is similar to that of FIG. 3(c).

FIG. 7(b) is a cross-sectional view taken along the line D-D of FIG. 7(a). With the piezoelectric vibrating piece 230, the thicknesses of the framing portion 132, the connecting portion 233, the connecting region 238c, and the mesa region 138a are formed at the thickness T2. Additionally, the thickness of the peripheral region 238b is formed at the thickness T1, which is thinner than the thickness T2. With the piezoelectric vibrating piece 230, forming the connecting portion 233 and the framing portion 132 with the same thickness and forming the connecting region 238c and the connecting portion 233 with the same thickness increases the mechanical strength of the connecting portion 233. Accordingly, the piezoelectric vibrating piece 230 is shock resistant to impacts such as from dropping.

### Constitution of the Piezoelectric Vibrating Piece 330

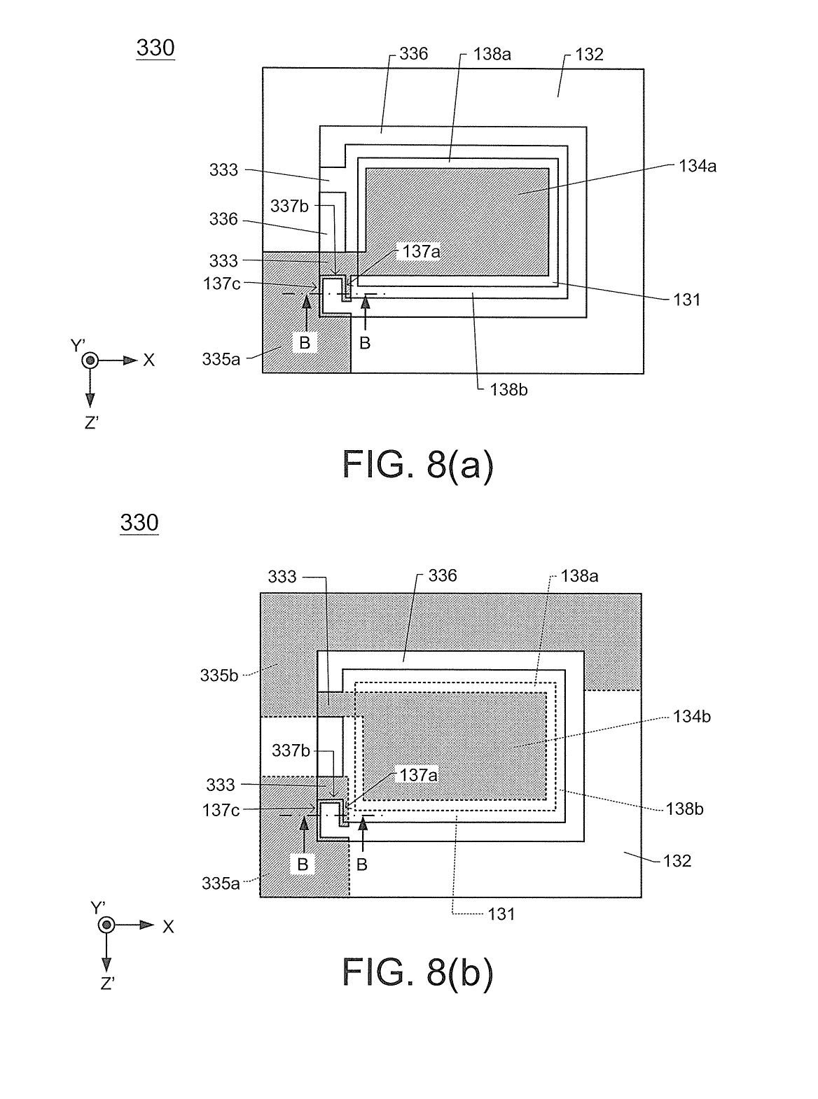

FIG. 8(a) is a plan view of the piezoelectric vibrating piece 330. The piezoelectric vibrating piece 330 includes the vibrator 131, the framing portion 132, and a connecting portion 333. The connecting portions 333 are respectively connected to the side at the −X-axis side and the +Z′-axis side and the side at the −X-axis side and the −Z′-axis side of the vibrator 131, extend in the −X-axis direction, and are connected to the framing portion 132. The connecting portion 333 has the same thickness as that of the peripheral region 138b. Additionally, the excitation electrode 134a is formed in the mesa region 138a on the surface at the +Y′-axis side. From the excitation electrode 134a, an extraction electrode 335a is extracted in the −X-axis direction. The extraction electrode 335a is formed to the −X-axis side and the +Z′-axis side of the framing portion 132 through the connecting portion 333 at the +Z′-axis side. The extraction electrode 335a is further extracted from the surface at the +Y′-axis side to the surface at the −Y′-axis side via the side surface 137a, a side surface 337b at the +Z′-axis side of the connecting portion 333 at the +Z′-axis side, and the side surface 137c. The cross section taken along the line B-B of FIG. 8(a) is similar to that of FIG. 3(c).

FIG. 8(b) is a plan view of the piezoelectric vibrating piece 330 on the surface at the −Y′-axis side viewed from the +Y′-axis side. The excitation electrode 134b is formed at the vibrator 131 on the surface at the −Y′-axis side. From the excitation electrode 134b, an extraction electrode 335b extends in the −X-axis direction. This extraction electrode 335b is formed to the +X-axis side and the −Z′-axis side of the framing portion 132 on the surface at the −Y′-axis side via the connecting portion 333 at the −Z′-axis side. The extraction electrode 335a is extracted from the surface at the +Y′-axis side to the surface at the −Y′-axis side via the side surfaces 137a, 337b, and 137c. The extraction electrode 335a is further extracted to the corner at the −X-axis side and the +Z′-axis side of the framing portion 132 on the surface at the −Y′-axis side.

Forming the two connecting portions 333 on the piezoelectric vibrating piece 330 provides shock resistance to withstand an impact such as from a drop. Additionally, similarly to the piezoelectric vibrating piece 130, extracting the extraction electrode 335a to −Y′-axis side via the taper-shaped side surface 137a of the vibrator 131 maintains a low crystal impedance (CI).

Representative embodiments are described in detail above; however, as will be evident to those skilled in the relevant art, this disclosure may be changed or modified in various ways within its technical scope.

Additionally, the above-described embodiments disclose a case where the piezoelectric vibrating piece is an AT-cut quartz-crystal vibrating piece. A BT-cut quartz-crystal vibrating piece or similar member that similarly vibrates in the thickness-shear mode is similarly applicable. Further, the piezoelectric vibrating piece is basically applicable to a piezoelectric material that includes not only a quartz-crystal material but also lithium tantalate, lithium niobate, and piezoelectric ceramics.

In the first aspect of the disclosure, the piezoelectric vibrating piece according to a second aspect is configured as follows. The extraction electrode is disposed at a taper-shaped side surface of the vibrator. The side surface is disposed adjacent to the connecting portion.

In the first aspect or second aspect of the disclosure, the piezoelectric vibrating piece according to a third aspect is configured as follows. The one of extraction electrodes is extracted from the one principal surface to the other principal surface via the side surface of the connecting portion.

In the first aspect to the third aspect of the disclosure, the piezoelectric vibrating piece according to a fourth aspect is configured as follows. The one of extraction electrodes is extracted from the one principal surface to the other principal surface via the side surface of the framing portion facing the vibrator.

In the first aspect to the fourth aspect of the disclosure, the piezoelectric vibrating piece according to a fifth aspect is configured as follows. At least one connecting portion is disposed.

A piezoelectric device according to a sixth aspect is configured as follows. The piezoelectric device includes a piezoelectric vibrating piece according to the first aspect to the fifth aspect. A base plate is bonded on another principal surface of the framing portion. A lid plate is bonded on one principal surface of the framing portion to seal the vibrator.

With the piezoelectric vibrating piece and the piezoelectric device according to the embodiments, an increase of a crystal impedance (CI) can be reduced.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a vibrator that vibrates at a predetermined vibration frequency, the vibrator including excitation electrodes on both principal surfaces, the vibrator being formed at a predetermined thickness;
a framing portion that surrounds a peripheral area of the vibrator; and
a connecting portion that connects the vibrator and the framing portion, wherein
the vibrator has a side surface, at least a part of the side surface being formed into a taper shape such that a thickness of the vibrator becomes thin as close to an outer periphery of the vibrator, and
the piezoelectric vibrating piece further includes an extraction electrode extracted from each of the excitation electrodes to the framing portion via the connecting portions, and
one of the extraction electrodes is extracted from one principal surface to another principal surface via a taper-shaped side surface of the vibrator.

2. The piezoelectric vibrating piece according to claim 1, wherein
the extraction electrode is disposed at a taper-shaped side surface of the vibrator, the side surface being disposed adjacent to the connecting portion.

3. The piezoelectric vibrating piece according to claim 1, wherein
one of the extraction electrodes is extracted from the one principal surface to the other principal surface via the side surface of the connecting portion.

4. The piezoelectric vibrating piece according to claim 1, wherein
one of the extraction electrodes is extracted from the one principal surface to the other principal surface via the side surface of the framing portion facing the vibrator.

5. The piezoelectric vibrating piece according to claim 1, wherein
at least one connecting portion is disposed.

6. A piezoelectric device, comprising:
the piezoelectric vibrating piece according to claim 1;
a base plate, being bonded on another principal surface of the framing portion; and
a lid plate, being bonded on one principal surface of the framing portion to seal the vibrator.
